(19) United States
(12) Patent Application Publication
(10) Pub. No.: US 2005/0103516 A1
(43) Pub. Date: May 19, 2005

(54) Flip-chip mounting circuit board, manufacturing method thereof and integrated circuit device

(75) Inventor: Tomohiko Kaneyuki, Tokyo (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: TDK Corporation, Tokyo (JP)

(21) Appl. No.: 10/955,934

(22) Filed: Sep. 29, 2004

(30) Foreign Application Priority Data
Sep. 30, 2003 (JP) 2003-341309

(51) Int. Cl. H05K 5/00

(52) U.S. Cl. 174/52.4

(57) ABSTRACT

A conductor pattern having joint portions to which electrodes of a semiconductor element chip are to be joined is formed on a board on which the semiconductor element chip is to be mounted. Further, a solder resist is formed on the board so as to be apart from both of adjacent joint portions by a predetermined distance and so as to space the adjacent joint portions from each other.

### CROSS REFERENCE TO RELATED APPLICATION

This application claims priority to Japanese Patent Application No. 2003-341309 filed on Sep. 30, 2003, and is incorporated herein by reference.

### BACKGROUND OF THE INVENTION

1. Field of the Invention

The present invention relates to a flip-chip mounting circuit board for mounting a semiconductor element chip thereon, a manufacturing method thereof, and an integrated circuit device.

2. Description of the Related Art

Recently, along with a request for downsizing electronic apparatuses, high-density packaging of circuit modules is demanded. For this demand, circuit boards are changed from both-surface wiring types to multilevel interconnection types and active elements are increasingly miniaturized. Further, semiconductor devices are changed from plastic mold semiconductors to bare chip semiconductors, and flip-chip mounting is developed as one of bare-chip mounting methods as disclosed in the Unexamined Japanese Patent Application KOKAI Publication No. H6-151506, Unexamined Japanese Patent Application KOKAI Publication No. H8-181239, and Unexamined Japanese Patent Application KOKAI Publication No. 2000-77471.

A conventional circuit board for flip-chip mounting will now be explained with reference to the drawings. FIG. 5 shows a plan view of a conventional circuit board 110. FIG. 6 shows a partial cross section of the circuit board 110 on which a semiconductor element chip 120 is flip-chip mounted.

As shown in FIG. 5 and FIG. 6, a conductor pattern 114 is formed on the surface of the circuit board 110. The semiconductor element chip 120 is mounted on a mounting region 118 (the region encircled by a chain line in FIG. 5) of the circuit board 110. As will be described later, the conductor pattern 114 is formed such that a bump electrode 124 of the semiconductor element chip 120 to be mounted overlaps a portion near the end portion of the conductor pattern 114. Further, as shown in FIG. 5 and FIG. 6, a solder resist 116 is coated so as to cover the surface of the circuit board 110 except the mounting region 118 for mounting the semiconductor element chip 120.

The semiconductor element chip 120 is flip-chip mounted on the circuit board 110 by the following procedures.

First, the semiconductor element chip 120 is positioned and placed on the circuit board 110. Note that by using a mask, a solder bump 122 is formed in advance on the bump electrode 124 of the semiconductor element chip 120 to be placed. Therefore, as shown in FIG. 6, the semiconductor element chip 120 is positioned such that the solder bump 122 thereof overlaps a joint portion 114a of the conductor pattern 114 on the circuit board 110.

After this, while the semiconductor element chip 120 is placed on the circuit board 110, the solder bump 122 is melted by reflow or the like, and the semiconductor element chip 120 and the circuit board 110 are mechanically and electrically connected. Next, an underfill resin 126 is filled into the space between the semiconductor element chip 120 and the circuit board 110 and then hardened. As a result, the circuit board 110 on which the semiconductor element chip 120 is flip-chip mounted is obtained.

Unexamined Japanese Patent Application KOKAI Publication No. H8-181239 discloses a structure in which the solder resist 116 is formed so as to cover almost the entire surface of the circuit board 110 except the joint portion 114a of the conductor pattern 114. For example, as shown in FIG. 7, there is such a package in which the semiconductor element chip 120 is flip-chip mounted on this circuit board 110 by the same procedures as described above. An opening 116a is formed in the solder resist 116 on the circuit board 110, and the joint portion 114a is exposed through the opening 116a.

Since flip-chip mounting does not require wires for connection, etc., devices can be downsized. However, product downsizing is more and more promoted lately, and semiconductors in which the interval between the bumps is 300 μm or less are required. In such a case, the conventional circuit boards shown in FIG. 5 to FIG. 7 have a problem in advancing further downsizing.

For example, the structure shown in FIG. 6, in which the solder resist 116 is not formed between the joint portions 114a, causes many short circuits after subjected to reliability test for thermal shock, etc., if the interval between the joint portions 114a, i.e. the interval between the bumps 122 is 300 μm or less. These short circuits are considered to be due to that the bumps 122 are likely to be dispersed because the solder resist 116 is not formed therebetween.

On the other hand, the structure shown in FIG. 7, in which the solder resist 116 is formed so as to almost entirely cover the conductor pattern 114, is likely to cause contact failures. This is considered to be due to that the solder resist 16 is likely to be left on the joint portion of the conductor pattern 14 that is to be jointed to the bump 122. Contact failures frequently occur if the breadth of the electrode formed by the conductor pattern 114 is about 50 to 80 μm.

As described above, the conventional circuit boards easily cause short circuits or contact failures, which might ruin high mounting efficiency (yield) and product reliability.

### BRIEF SUMMARY OF THE INVENTION

In consideration of the above-described circumstance, an object of the present invention is to provide a flip-chip mounting circuit board which can be downsized with its high yield and reliability kept, a manufacturing method of such a circuit board, and an integrated circuit device.

Another object of the present invention is to provide a flip-chip mounting circuit board which can prevent a short circuit between adjacent bumps and realize a desirable bump-electrode contact between the circuit board itself and an element mounted thereon, a manufacturing method of such a circuit board, and an integrated circuit device.

To achieve the above objects, a flip-chip mounting circuit board according to a first aspect of the present invention comprises:
a board on which a semiconductor element chip is to be mounted;
a conductor pattern which is provided on the board and includes joint portions to which electrodes of the semiconductor element chip are to be jointed; and
a solder resist which is provided so as to be apart from the joint portions and spaces adjacent two of the joint portions from each other.

To achieve the above objects, a manufacturing method of a flip-chip mounting circuit board according to a second aspect of the present invention comprises:
a step of preparing a board on which a semiconductor element chip is to be mounted;
a step of forming on the board, a conductor pattern having joint portions to which electrodes of the semiconductor element chip are to be jointed; and
a step of forming a solder resist which is provided so as to be apart from the joint portions and so as to space adjacent two of the joint portions from each other.

To achieve the above objects, an integrated circuit device according to a third aspect of the present invention comprises:
a board;
a conductor pattern provided on the board;
a semiconductor element chip whose electrodes are jointed to the conductor pattern; and
a flip-chip mounting circuit board having a solder resist which is provided so as to be apart from joint portions at which the conductor pattern and the electrodes are jointed, and spaces adjacent two of the joint portions from each other.

### BRIEF DESCRIPTION OF THE DRAWINGS

These objects and other objects and advantages of the present invention will become more apparent upon reading of the following detailed description and the accompanying drawings in which:

FIG. 1 is a plan view of a flip-chip mounting circuit board according to an embodiment of the present invention;

FIG. 2 is a plan view showing a semiconductor element chip mounted on the flip-chip mounting circuit board according to the embodiment of the present invention;

FIG. 3 is a cross section of the flip-chip mounting circuit board in a state where a semiconductor element chip is mounted thereon;

FIG. 4 is a diagram showing a modified example of the flip-chip mounting circuit board according to the embodiment of the present invention;

FIG. 5 is a plan view of a conventional flip-chip mounting circuit board;

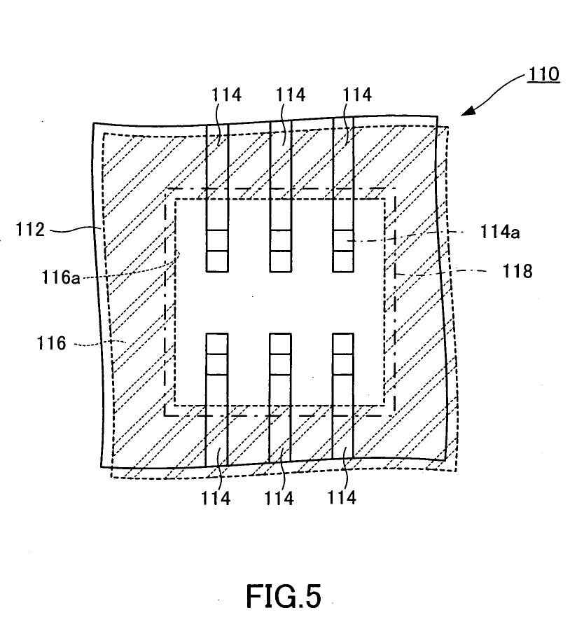

FIG. 6 is a cross section of the conventional flip-chip mounting circuit board in a case where a semiconductor element chip is mounted thereon; and

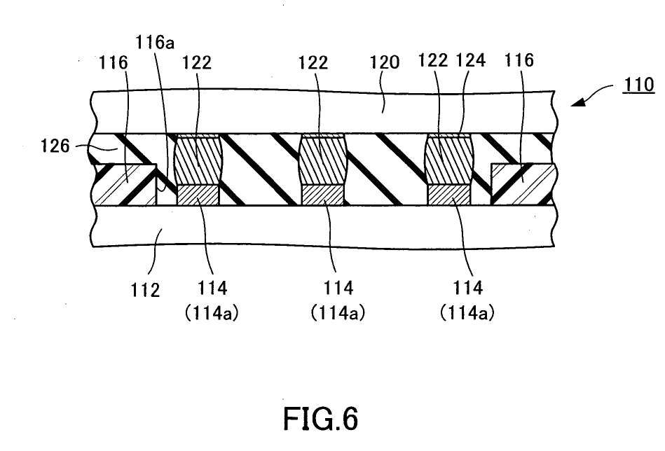

FIG. 7 is a cross section of a conventional flip-chip mounting circuit board in a state where a semiconductor element chip is mounted thereon.

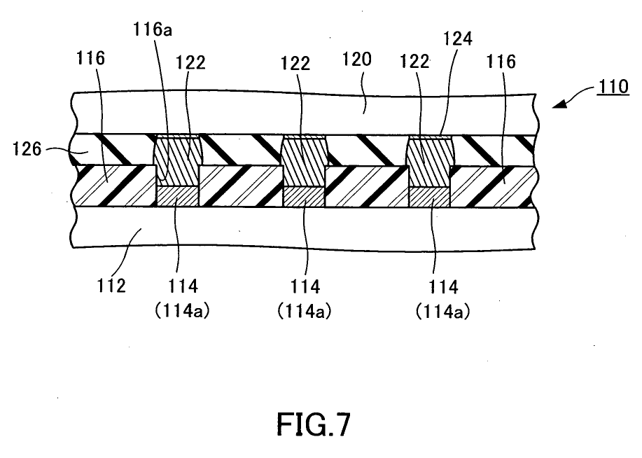

### DETAILED DESCRIPTION OF THE INVENTION

A flip-chip mounting circuit board, a manufacturing method thereof, and an integrated circuit device according to an embodiment of the present invention will be explained in detail with respect to the drawings.

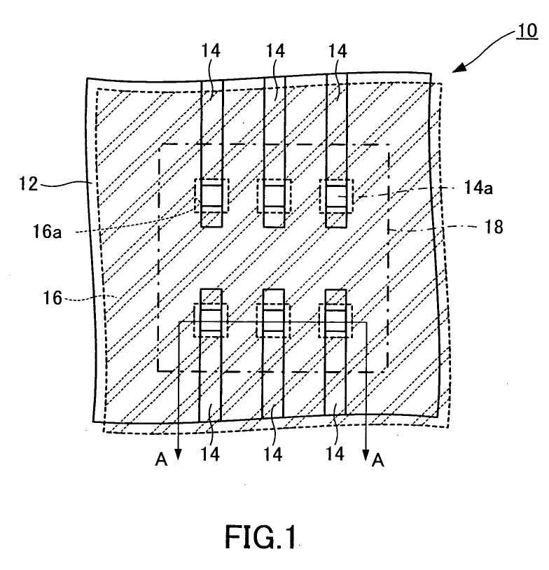

FIG. 1 shows an example of the structure of the flip-chip mounting circuit board 10 according to an embodiment of the present invention. In FIG. 1, for easier understanding, the region on which a semiconductor element chip 20 is to be mounted is illustrated as a mounting region 18 (the region indicated by a chain line in FIG. 1). Further, in FIG. 1, for easier understanding, the end of a solder resist 16 and the end of a board 12 are deviated. However, the solder resist 16 is actually formed on almost the entire surface of the board 12.

A flip-chip mounted circuit is a circuit obtained by mounting the semiconductor element chip 20 on the flip-chip mounting circuit board 10. An integrated circuit device is a device having this flip-chip mounted circuit.

The flip-chip mounting circuit board 10 according to the present embodiment comprises the board 12, a conductor pattern 14, and the solder resist 16, as shown in FIG. 1.

The board 12 is constituted by, for example, a printed circuit board.

The conductor pattern 14 is made of, for example, copper, and is formed on the surface of the board 12 by etching or the like, using a predetermined pattern. A portion of the conductor pattern 14 that is near the end portion of the conductor pattern 14 is exposed through an opening 16a in the solder resist 16. This portion is formed so as to overlap a bump 22 provided on the semiconductor element chip 20 to be described later. In the example shown in FIG. 1, the conductor pattern 14 is jointed to the bump 22 of the semiconductor element chip 20 at a joint portion 14a of the end portion.

As will be described later, the solder resist 16 has an opening 16a spaced from the joint portion 14a by a predetermined breadth, and is formed to cover almost the entire surface of the board 12 including the mounting region 18 (the region encircled by the chain line in FIG. 1) for mounting the semiconductor element chip 20. The joint portion 14a of the conductor pattern 14 is exposed through this opening 16a. As a result, adjacent joint portions 14a are spaced by the solder resist 16. In this specification, “adjacent” means that components have the shortest relative distance therebetween.

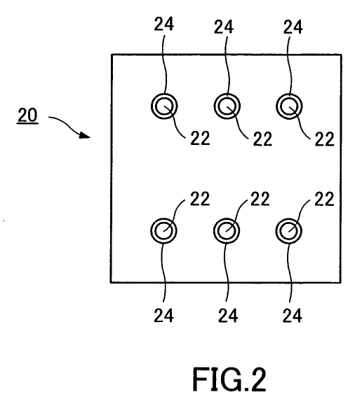

FIG. 2 shows the semiconductor element chip 20 to be mounted on the circuit board 10.

The semiconductor element chip 20 comprises bumps 22 and bump electrodes 24.

The bump electrodes 24 are made of, for example, aluminum or the like, and are arranged so as to be spaced apart from each other by a predetermined breadth.

The bumps 22 are made of gold or the like, and are formed on the bump electrodes 24 to have a sphere shape having a predetermined radius, by printing, plating, vapor deposition, etc.

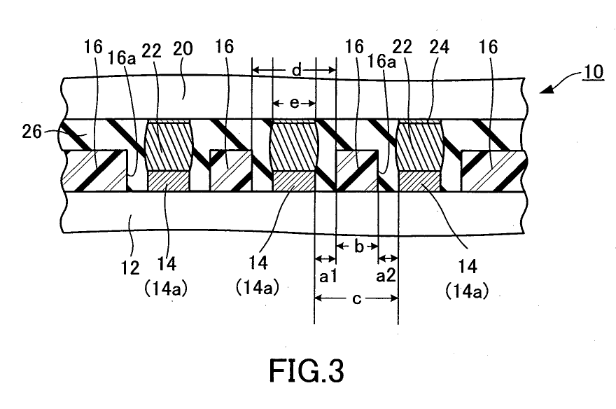

FIG. 3 shows a cross section of the circuit board 10 on which the semiconductor element chip 20 is mounted, as sectioned along a line A-A shown in FIG. 1.

As shown in FIG. 3, the semiconductor element chip 20 is mounted such that the bumps 22 go into the openings 16a of the solder resist 16. The bumps 22 are jointed to the bump electrode 24 of the semiconductor element chip 20 and to the conductor pattern 14, for electrically connecting these with each other.

The semiconductor element chip 20 and the circuit board 10 are interveningly supported by the bumps 22, and the space between them is sealed by an underfill resin 26. The semiconductor element chip 20 and the circuit board 10 are firmly secured to each other by the underfill resin 26.

According to the present embodiment, as shown in FIG. 3, the solder resist 16 is provided between adjacent joint portions 14a such that it is spaced from both of the adjacent joint portions 14a by a predetermined distance. In the following explanation, the solder resist 16 is formed with respect to the joint portions 14a, but may be formed with respect to the bumps 22.

The distances a1 and a2 between the solder resist 16 and each of the adjacent joint portions 14a are determined by mask mating accuracy at the time of patterning the solder resist 16 as will be described later, but are preferably 30 μm or more.

In the present example, in consideration of the possibility that the solder resist 16 might be displaced toward the conductor pattern 14 by approximately 30 μm when it is patterned, the solder resist 16 is formed to have a margin of 30 μm or more from the joint portion 14a.

Accordingly, a difference between a distance “c” between the joint portions 14a and a breadth “b” of the solder resist 16 (the difference=a1+a2) is preferably 60 μm or more. In other words, the breadth “b” of the solder resist 16 is set to be smaller than the distance “c” between the adjacent joint portions 14a by preferably 60 μm or more.

Further, in other words, a breadth “d” of the opening 16a of the solder resist 16 is set to be larger than a maximum breadth “e” of the joint portion 14a by preferably 60 μm or more.

A manufacturing method of the flip-chip mounting circuit board 10 according to the present embodiment and a flip-chip mounting method using the flip-chip mounting circuit board 10 will now be explained. The present invention is not limited to the example to be described below but may include other examples as long the same result can be obtained by such examples.

First, the board 12 is prepared and a conductor film of copper or the like is formed on the board 12. Next, the conductor film is patterned to have a predetermined shape, thereby forming the conductor pattern 14.

Next, the solder resist 16 is formed on the board 12, and the openings 16a are formed in the solder resist 16 by patterning. At this time, the breadth “d” of the opening 16a is formed to be larger than the maximum breadth “e” of the joint portion 14a by preferably 60 μm or more as described above.

As a result, the flip-chip mounting circuit board 10 according to the present embodiment is formed.

At the time of flip-chip mounting, the semiconductor element chip 20 is mounted on this circuit board 10 by being positioned such that the bumps 22 printed thereon contact the conductor pattern 14 exposed through the openings 16a. In this state, the bumps 22 are melted by applying a heat treatment such as a reflow process or the like, thereby the semiconductor element chip 20 and the conductor pattern 14 are mechanically and electrically connected.

After this, the underfill resin 26 is poured into the space between the semiconductor element chip 20 and the circuit board 10 on an inclined hot plate. Then, the circuit board 10 on which the semiconductor element chip 20 is mounted is taken off from the hot plate and the underfill resin 20 is hardened.

By this, the semiconductor element chip 20 is securely fixed to the circuit board 10. By following these steps, the semiconductor element chip 20 is flip-chip mounted on the circuit board 10.

As described above, according to the present embodiment, the solder resist 16 is formed so as to space adjacent joint portions 14a from each other as shown in FIG. 2. This structure can more prevent the bumps 22 from being dispersed and thereby suppress and reduce short circuits between the bumps 22 than a structure having no solder resist 16 between the joint portions 14a, in a case where the interval between the joint portions 14a is fined down to 300 μm or less.

Further, according to the present embodiment, the solder resist 16 is formed to be spaced apart from the joint portion 14a by a predetermined distance, for example, 30 μm or more. This distance is set in consideration of a possible displacement of the solder resist 16 depending on the mask mating accuracy at the time of patterning the solder resist 16. That is, in the present example, the solder resist 16 is formed to have a margin of 30 μm or more from the joint portion 14a, with a possibility taken into consideration that the solder resist 16 might be displaced toward the conductor pattern 14 by approximately 30 μm at the time of patterning. By forming the openings 16a in consideration of the mask mating accuracy, it is possible to prevent a contact failure between the bumps 22 and the conductor pattern 14 which is due to the solder resist 16 being formed to overlap the bumps 22. Consequently, mounting failures can be reduced.

Therefore, according to the present embodiment, it is possible to reduce short circuits between the bumps 22 and contact failures of the bumps 22, and thereby to improve the yield and reliability.

Further, since the solder resist 16 has the openings 16a having a breadth larger than that of the joint portions 14a by a predetermined degree, the bumps 22 can easily be introduced into the openings 16a at the time of mounting, which improves the mounting efficiency.

The present invention is not limited to the above-described embodiment, but may be modified and applied in various ways. For example, according to the above-described embodiment, the conductor pattern 14 is directly jointed to the bumps 22. However, a connection electrode layer which is electrically connected to the conductor pattern 14 may be provided, and the bumps 22 may be jointed thereto.

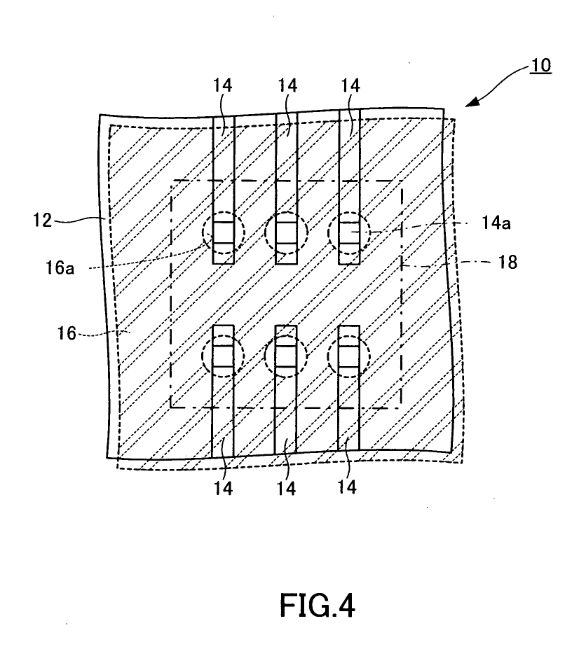

According to the above-described embodiment, the openings 16a having a rectangular shape are formed in the solder resist 16. However, the shape of the openings 16a is not limited to this, but may be other polygons or may be a circle as shown in FIG. 4. In a case where the openings 16a are formed into a circle, the bumps 22 can be more easily introduced into the openings 16a because the bumps 22 are generally spherical. This improves the mounting efficiency. The structure having circular openings 16a is particularly effective for mounting a semiconductor element chip 20 in which the bumps 22 are arranged in a staggered state.

According to the above-described embodiment, the solder resist 16 is spaced apart from the joint portion 14a by 30 μm or more. However, this distance (margin) is determined by the mask mating accuracy. Accordingly, if patterning with a high degree of accuracy is available, the distance may be smaller than 30 μm.

Further, according to the above-described embodiment, the breadth of the openings 16a of the solder resist 16 is set based on the joint portions 14a. However, a breadth “e” of the bumps 22 may be used as the base.

In this case too, the distance between the solder resist 16 and the bump 22 is determined by the mask mating accuracy at the time of patterning the solder resist 16, as described above. For example, in a case where the solder resist 16 might be displaced toward the conductor pattern 14 by approximately 30 μm when the solder resist 16 is patterned, the solder resist 16 may be formed to have a margin of 30 μm or more from the bumps 22.

Further, since the breadth of the bumps 22 is changed after the reflow process, the breadth of the bumps 22 before mounting, i.e. the diameter of the sphere in case of the bumps being spherical, may be used as the base.

According to the present invention, it is possible to provide a flip-chip mounting circuit board which can be downsized with its high yield and reliability kept, a manufacturing method thereof, and an integrated circuit device.

Further, according to the present invention, it is possible to provide a flip-chip mounting circuit board which can prevent a short circuit between adjacent bumps and realize a desirable bump-electrode contact between the circuit board itself and an element mounted thereon, a manufacturing method thereof, and an integrated circuit device.

Various embodiments and changes may be made thereunto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. 2003-341309 filed on Sep. 30, 2003 and including specification, claims, drawings and summary. The disclosure of the above Japanese Patent Application is incorporated herein by reference in its entirety.

1. A flip-chip mounting circuit board comprising:
a board on which a semiconductor element chip is to be mounted;
a conductor pattern which is provided on said board and includes joint portions to which electrodes of the semiconductor element chip are to be jointed; and
a solder resist which is provided so as to be apart from said joint portions and spaces adjacent two of said joint portions from each other.

2. The flip-chip mounting circuit board according to claim 1,
wherein said solder resist has a breadth narrower than an interval between the adjacent two of said joint portions.

3. The flip-chip mounting circuit board according to claim 2,
wherein the breadth of said solder resist is smaller than the interval between the adjacent two of said joint portions by 60 μm or more.

4. The flip-chip mounting circuit board according to claim 1,
wherein said solder resist is apart from said joint portions by 30 μm or more.

5. The flip-chip mounting circuit board according to claim 1,
wherein said solder resist has openings which are formed to surround said joint portions.

6. The flip-chip mounting circuit board according to claim 5,
wherein said openings are formed to have a rectangular shape.

7. The flip-chip mounting circuit board according to claim 5,
wherein said openings are formed to have a circular shape.

8. A flip-chip mounting circuit board comprising:
a board on which a semiconductor element chip is to be mounted;
a conductor pattern which is provided on said board and includes joint portions to which electrodes of the semiconductor element chip are to be jointed; and
a solder resist which is formed so as to cover said board and includes openings which are formed so as to be larger than said joint portions by a predetermined breadth at positions corresponding to said joint portions.

9. A flip-chip mounting circuit board comprising:
a board on which a semiconductor element chip is to be mounted;
a conductor pattern which is provided on said board and includes joint portions to which electrodes of the semiconductor element chip are to be jointed; and
a solder resist which is formed on said board so as to surround said joint portions of said conductor pattern.

10. A flip-chip mounting circuit board comprising:
a board on which a semiconductor element chip having bumps is to be mounted;
a conductor pattern which is provided on said board and includes joint portions to which the bumps of the semiconductor element chip are to be jointed; and
a solder resist which is formed so as to cover said board and includes openings which are formed so as to be larger than the bumps by a predetermined breadth at positions to which the bumps are jointed.

11. A flip-chip mounting circuit board comprising:
a board on which a semiconductor element chip having bumps is to be mounted;
a conductor pattern which is provided on said board and includes joint portions to which the bumps of the semiconductor element chip are to be jointed; and
a solder resist which is formed correspondingly to positions on said board at which the bumps are to be jointed and formed so as to surround the bumps.

12. A manufacturing method of a flip-chip mounting circuit board comprising:
a step of preparing a board on which a semiconductor element chip is to be mounted;
a step of forming on said board, a conductor pattern having joint portions to which electrodes of the semiconductor element chip are to be jointed; and
a step of forming a solder resist which is provided so as to be apart from said joint portions and so as to space adjacent two of said joint portions from each other.

13. An integrated circuit device comprising:
a board;
a conductor pattern provided on said board;
a semiconductor element chip whose electrodes are jointed to said conductor pattern; and
a flip-chip mounting circuit board having a solder resist which is provided so as to be apart from joint portions at which said conductor pattern and said electrodes are jointed, and spaces adjacent two of said joint portions from each other.
